(19) United States
(12) Patent Application Publication
(10) Pub. No.: US 2011/0233643 A1
(43) Pub. Date: Sep. 29, 2011

(54) PMOS Flash Cell Using Bottom Poly Control Gate

(75) Inventor: Julian CHANG, Hsinchu (TW)

(73) Assignee: CHINGIS TECHNOLOGY CORPORATION, HSINCHU (TW)

(21) Appl. No.: 12/729,240

(22) Filed: Mar. 23, 2010

(51) Int. Cl. H01L 29/788

(52) U.S. Cl. 257/319; 257/E29.3

(57) ABSTRACT

A two-transistor PMOS memory cell has a selective gate (SG) PMOS and a floating gate (FG) PMOS is provided. A control gate, overlapping the floating gate of the FG PMOS, of the memory cell is made by a polysilicon layer and located on an isolation structure.

### BACKGROUND

1. Technical Field

The disclosure relates to PMOS flash memory. More particularly, the disclosure relates to multiple time programmable (MTP) PMOS flash memory.

2. Description of Related Art

A single-poly non-volatile EEPROM cell includes only one polysilicon layer and is thus advantageous since the memory cell and its associated logic circuitry may be fabricated using the same semiconductor fabrication process. The single-poly cell includes a floating gate which overlies a channel region extending between source and drain regions of the memory cell. The single-poly cell includes a buried control gate that is capacitively coupled to the floating gate in a manner similar to that of an MOS capacitor. Although early single-poly memory cells were primarily fabricated using NMOS technology, recent advances in the semiconductor industry have led to the development of a PMOS single-poly floating gate memory cell such as, for instance, that disclosed in U.S. Pat. No. 5,736,764 entitled “PMOS Flash EEPROM Cell with Single Poly”.

In U.S. Pat. No. 7,078,761, the single-poly EEPROM cell is further improved by positioning the control gate in a second N-well to keep the control gate electrically isolated from the first N-well where the floating gate transistor and the selective gate transistor are located. However, the density is limited by the relatively large area for the control gate if electrically erasing the memory cell is desired.

### SUMMARY

Accordingly, a two-transistor PMOS memory cell has a selective gate (SG) PMOS and a floating gate (FG) PMOS is provided. A control gate, overlapping the floating gate of the FG PMOS, of the memory cell is made by a polysilicon layer and located on an isolation structure.

It is to be understood that both the foregoing general description and the following detailed description are by examples, and are intended to provide further explanation of the invention as claimed.

### BRIEF DESCRIPTION OF THE DRAWINGS

FIG. 1 is a top view of a multiple-time programming (MTP) two-transistor (2T) PMOS flash cell according to an embodiment of the invention.

FIG. 2 is a cross-sectional view of the MTP 2T PMOS flash cell taken along line II-II in FIG. 1.

### DETAILED DESCRIPTION

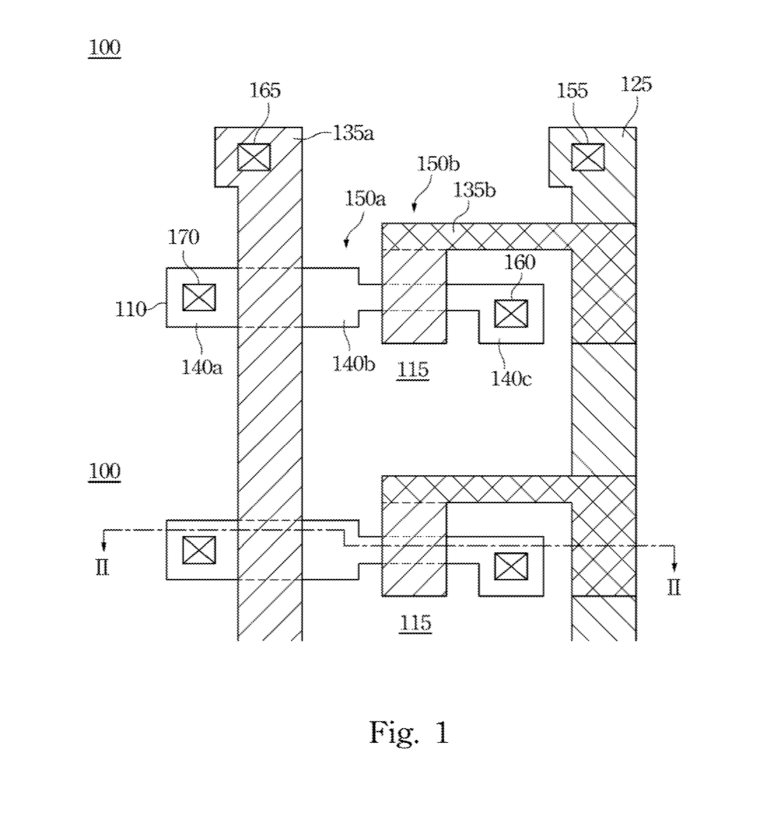

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing. FIG. 1 is a top view of a multiple-time programming (MTP) two-transistor (2T) PMOS flash cell according to an embodiment of the invention. In FIG. 1, each MTP 2T PMOS flash cell 100 has a selective gate (SG) PMOS 150a and a floating gate (FG) PMOS 150b. The SG PMOS 150a has a selective gate 135a, and the FG PMOS 150b has a floating gate 135b.

A first P⁺ doped region 140a serves as the source of the SG PMOS 150a, and a second P⁺ doped region 140b serves as the drain of the SG PMOS 150a. In the meantime, the second P⁺ doped region 140b also serves as the source of the FG PMOS 150b, and a third P⁺ doped region 140c serves as the drain of the FG PMOS 150b. The first P⁺ doped region 140a, the second P⁺ doped region 140b and the third P⁺ doped region 140c are all located in the N-well 110.

A control gate 125 is located on the isolation structure 115 and electrically isolated from the N-well 110. The isolation structure 15 can be field oxide (FOX) or shallow trench isolation (STI), for example. The control gate 155, the selective gate 153a, the first P⁺ doped region 140a, and the third P⁺ doped region 140c respectively have contact 155, 165, 170, and 160 to enable electrical connection with other metal interconnects.

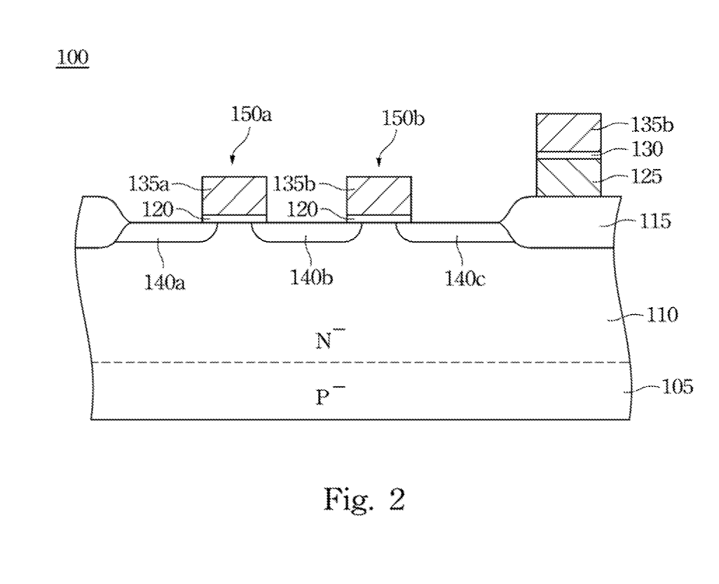

FIG. 2 is a cross-sectional view of the MTP 2T PMOS flash cell taken along line II-II in FIG. 1. In FIG. 2, it can be seen clearly that the control gate 125 is made by a first polysilicon layer on the isolation structure 115. Then, a second dielectric layer 130 is formed on the control gate 125 to electrically separate the control gate 125 and the floating gate 135b.

Both of the SG PMOS 150a and the FG PMOS 150b are formed in the N-well 110 in a P-type substrate 105. The selective gate 135a and the floating gate 135b are made by a second polysilicon layer and electrically isolated from the N-well by a first dielectric layer 120.

The operations, such as programming, erasing and reading, of the above MTP 2T PMOS flash cell is not changed by the new design of the control gate and hence is omitted here.

Accordingly, since the control gate is made by a polysilicon layer on the isolation structure, instead of a diffusion area in a separate N-well, the very large N-well-to-N-well isolation layout rule required in the previously patented MTP cell is replaced with very small poly-to-diffusion layout rule. Therefore, the occupied area of the unit memory cell can be reduced to about 20%.

The reader's attention is directed to all papers and documents which are filed concurrently with this specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A two-transistor PMOS memory cell, comprising:
a selective gate (SG) PMOS having a drain and a source located in a N-well;
a floating gate (FG) PMOS having a source and a drain located in the N-well, wherein the drain of the SG PMOS is the same as the source of the FG PMOS; and
a control gate made by a first polysilicon layer and located on an isolation structure, wherein the control gate overlaps an extension of the floating gate of the FG PMOS.

2. A two-transistor PMOS memory cell of claim 1, wherein the selective gate and the floating gate are made by a second polysilicon layer.

3. A two-transistor PMOS memory cell of claim 1, wherein the isolation structure is field oxide or shallow trench isolation.

4. A two-transistor PMOS memory array, comprising
a plurality of selective gate (SG) PMOSs having a strip of selective gate, wherein each SG PMOS has a drain and a source;
a plurality of floating gate (FG) PMOSs, wherein the each FG PMOS has a floating gate, a source and a drain, and the drain of the each SG PMOS is the same as the source of the each FG PMOS; and
a strip of control gate made by a first polysilicon layer and located on an isolation structure, wherein the control gate overlaps an extension of the floating gate of the each FG PMOS.

5. The two-transistor PMOS memory array of claim 4, wherein the control gate has only one contact on an end of the control gate.

6. The two-transistor PMOS memory array of claim 4, wherein the selective gate and the floating gates are made by a second polysilicon layer.

7. The two-transistor PMOS memory array of claim 4, wherein the isolation structure is field oxide or shallow trench isolation.
